(19) United States
(12) Patent Application Publication
(10) Pub. No.: US 2026/0257583 A1
(43) Pub. Date: Sep. 3, 2026

(54) DEMAND RESPONSE SYSTEMS AND METHODS FOR BATTERY MANAGEMENT SYSTEMS

(71) Applicant: Electrovaya Inc., Mississauga (CA)

(72) Inventors: Rajshekar DasGupta, Oakville (CA); Harry Young, Guelph (CA); Elmira Memarzadeh Lotfabad, Mississauga (CA)

(21) Appl. No.: 19/653,672

(22) Filed: Apr. 21, 2026

Related U.S. Application Data
(63) Continuation of application No. PCT/IB2024/062159, filed on Dec. 3, 2024.
(60) Provisional application No. 63/624,565, filed on Jan. 24, 2024.

(51) Int. Cl. B60L 53/67; B60L 53/16; B60L 53/62; B60L 58/12; B60L 58/16

(52) U.S. Cl. CPC B60L 53/67; B60L 53/16; B60L 53/62; B60L 58/12; B60L 58/16; B60L 2240/72; B60L 2240/80

(57) ABSTRACT

In accordance with various embodiments, a system and a method for managing a fleet of electric vehicles are provided. The system/method may include a power source, a plurality of charging connectors configured to supply a current to one or more electric vehicles of the fleet, and a processor configured to execute instructions that cause the processor to receive an instruction comprising a power distribution scheme for charging one or more electric vehicles of the fleet, obtain a dataset associated with the fleet, wherein the dataset comprises one or more data features from a list comprising dynamic data and historical usage data associated with the fleet, analyze the one or more data features using a machine learning model to generate a predicted action, and instruct the power source to distribute power to the one or more electric vehicles of the fleet according to the predicted action.

### CROSS-REFERENCE TO RELATED APPLICATIONS

The present application is a continuation of International Application No. PCT/IB2024/062159, filed December 3, 2024, which claims priority to U.S. Patent Application No. 63/624,565, filed January 24, 2024, all of which are incorporated by reference herein in their entirety.

### FIELD OF INVENTION

The disclosure relates to electric vehicles and electrochemical energy storage devices including rechargeable lithium-ion batteries, and more particularly related to methods and systems for managing such battery systems and electric vehicles that use such electrical energy storage devices.

### BACKGROUND

The demand for rechargeable lithium-based battery technologies with improved performance, particularly related to charging and health of the batteries, is ever-increasing with the upticks in the accelerating adoption of passenger and commercial electric vehicles. Rising along with the commercial demand is the need for management of the fleet of such battery-operated vehicles. It is, however, not straightforward to manage these vehicles, at least with respect to the charging and maintenance the battery units in order to prolong the performance and longevity of such batteries, while minimizing the cost of operations by lowering charging cost for the fleet. Considering all the above, the added challenge to the above lies in the fact that these vehicles are manufactured by different companies, which may use different batteries with vastly different battery chemistries, form factors with different physical dimensions and capacities, and/or often with different specificities in charge and discharge characteristics and limits applied to the batteries.

Even if the battery parameters are similar, the charge/discharge states or rates of any given battery or any electric vehicle with such battery is highly time dependent in their usage cycle. In other words, at any given time, the state of charge (SOC), state of health (SOH), operating voltages or current ratings for each of the vehicle batteries may be uniquely different from another one. Thus, in order to ensure safety of a fleet of electric vehicles with respect to maintaining a high performance and longevity of their battery units, and to avoid a complete system shutdown in some instances, there is a need for a battery management system that is capable of managing the fleet. Specifically, there is a need for a battery management system that is capable of managing the fleet with a broad range of battery chemistries, characteristics, performance, while accommodating unforeseen variations in time-dependent power, voltage, and current ratings and extraneous circumstances.

### BRIEF DESCRIPTION OF THE DRAWINGS

For a more complete understanding of the principles disclosed herein, and the advantages thereof, reference is now made to the following descriptions taken in conjunction with the accompanying drawings, in which:

FIG. 1 illustrates an embodiment of a management system for a fleet of electric vehicles and/or a set of electrical energy storage devices/batteries, in accordance with various embodiments.

FIG. 2 illustrates a block diagram of a computer system/processor used in the management system of FIG. 1, in accordance with various embodiments.

FIG. 3A illustrates an example machine learning model or a neural network training process used in in the management system of FIG. 1, in accordance with one or more embodiments.

FIG. 3B illustrates a validation process for the neural network of FIG. 3A, in accordance with one or more embodiments.

FIG. 4 illustrates a method of managing a fleet of electric vehicles and/or a set of electrical energy storage devices/batteries, in accordance with various embodiments.

FIG. 5 illustrates example predicted actions generated by a machine learning model used in the management system of FIG. 1, in accordance with various embodiments.

It is to be understood that the figures are not necessarily drawn to scale, nor are the objects in the figures necessarily drawn to scale in relationship to one another. The figures are depictions that are intended to bring clarity and understanding to various embodiments of apparatuses, systems, and methods disclosed herein. Wherever possible, the same reference numbers will be used throughout the drawings to refer to the same or like parts. Moreover, it should be appreciated that the drawings are not intended to limit the scope of the present teachings in any way.

### DETAILED DESCRIPTION

The following shall be a detailed description of the drawings which are given for the purposes of illustrating the preferred embodiments of the present invention, and not for the purpose of limiting the same. In accordance with one or more embodiments, a system and a method for managing a fleet of electric (or battery-operated) vehicles and a set of electrical energy storage devices are disclosed. The system and method disclosed herein may be implemented to mitigate any issues related to charging a fleet of electric vehicles and a set of electrical energy storage devices when a utility charging and/or customer power demand request is implemented at a power distribution source. The disclosed system and method may be capable of charging electric vehicles based on specific utility charging and/or customer power demand requests, various battery parameters, and the behavioral patterns of operators, etc. The resulting action at the power source may include determining an optimal current for charging a specific electric vehicle of the fleet, including derating of the chargers for a specific electric vehicle may be needed as part of the management system. The action may include determining a charge limit for a specific electric vehicle of the fleet, determining a charge duration for a specific electric vehicle of the fleet, determining that one or more specific electric vehicles of the fleet receives power from the power source; and/or determining that one or more specific electric vehicles of the fleet discontinues receiving power from the power source. Since conventional charging is done using equal load across all vehicles regardless of the battery’s parameters, optimizing which and how much to charge a specific electric vehicle or a specific electrical storage device may be implemented via the disclosed system/method. Moreover, in order to preserve longevity, overall safety of the electrical storage devices or electrical storage devices used in the electric vehicles, a derated current versus increased charging time for the electrical storage devices or electrical storage devices used in the electric vehicles may be determined using one or more machine learning models as disclosed herein.

An electrical energy storage device is also referred to herein as a battery pack, a battery unit, a battery module, or simply, a battery. The disclosed electrical energy storage device may be used to power any electric vehicle, include hybrid or plug-in type vehicles, including, but not limited to, a forklift, a bus, etc. In various embodiments, the system/method for managing a fleet of electric vehicles or a set of electrical energy storage devices may include a power source, a plurality of charging connectors coupled to the power source, where the plurality of charging connectors can be configured to supply a current from the power source to one or more electric vehicles of the fleet or one or more electrical energy storage devices. The system may include a processor configured to execute instructions (machine-readable or computer-readable) borne by a non-transitory computer-readable memory device, including computer-readable devices. In one or more embodiments, the processor/system may receive an instruction (or a demand request) from an external source, such as a user, an operator, a utility operator, or any input from outside of the system. The instruction received may include, for example, but not limited to, a power distribution scheme for charging one or more electric vehicles of the fleet. The instruction maybe received during a power outage, during high use or busy hours, or any circumstances that would require the power source to operate at a limited level to accommodate such circumstances.

In accordance with one or more embodiments, the disclosed system/method may be configured to manage power consumption of a fleet of electric vehicles or a set of electrical energy storage devices in response to conditions in an electric utility wholesale market. Electric utilities may communicate demand requests to customers in many ways, including off-peak metering, in which electricity rates are lower at certain times of the day, or smart metering, in which real-time demand requests (referred to herein as instructions received by the system or the processor/computing device/computing system) or changes in price can be informed to customers. The disclosed system/method may be implemented to evaluate these real-time demand requests and derate input charger current of the one or more electric vehicles or one or more electrical energy storage devices, accordingly.

Once the instruction that includes the power distribution scheme is received by the processor/computer at the system, the process may obtain a dataset associated with the fleet of electric vehicles. The dataset may include one or more data features from a list comprising dynamic data and historical usage data associated with the fleet of electric vehicles. The processor/system may further analyze, in response to the instruction, the one or more data features using a machine learning model to generate a predicted action that the system can take based on the circumstances. The processor/system may then instruct the power source to distribute power to the one or more electric vehicles of the fleet according to the predicted action. In one or more embodiments, the predicted action may include one of many, including, but not limited to, determining an optimal current for charging a specific electric vehicle of the fleet; determining a charge limit for a specific electric vehicle of the fleet; determining a charge duration for a specific electric vehicle of the fleet; determining that one or more specific electric vehicles of the fleet receives power from the power source; or determining that one or more specific electric vehicles of the fleet discontinues receiving power from the power source. In some embodiments, the power distribution scheme may include a special instruction to curtail power distribution by the power source, for example, restricting the power source’s availability to supply to the individual electric vehicles. In some embodiments, the power distribution scheme may include an instruction to limit a maximum energy capacity or power available to the power source for distribution. In some embodiments, the power distribution scheme may include an instruction to set a duration or a period of time for curtailment of power distribution by the power source.

In accordance with various embodiments, the system/method for managing a set of electrical energy storage devices is provided. The system/method may include a power source, a plurality of charging connectors coupled to the power source, the plurality of charging connectors configured to supply a current from the power source to one or more electrical energy storage devices of the set. The system may also include a processor (or a computing device) that is configured to execute machine-readable instructions borne by a non-transitory computer-readable memory device. The executable instructions may cause the processor to receive an instruction from an external source. The instruction received may include a power distribution scheme for charging one or more electrical energy storage devices and obtain a dataset associated with the set of electrical energy storage devices. The dataset may include one or more data features from a list comprising dynamic data and historical usage data associated with the set of electrical energy storage devices. The processor/system can then proceed to analyze, in response to the instruction received, the one or more data features using a machine learning model to generate a predicted action and instruct the power source to distribute power to the one or more electrical energy storage devices of the set according to the predicted action. In one or more embodiments, the predicted action may include determining an optimal current for charging a specific electrical energy storage device of the set, determining a charge limit for a specific electrical energy storage device of the set, determining a charge duration for a specific electrical energy storage device of the set, determining that one or more specific electrical energy storage devices of the set receives power from the power source, and/or determining that one or more specific electrical energy storage devices of the set discontinues receiving power from the power source.

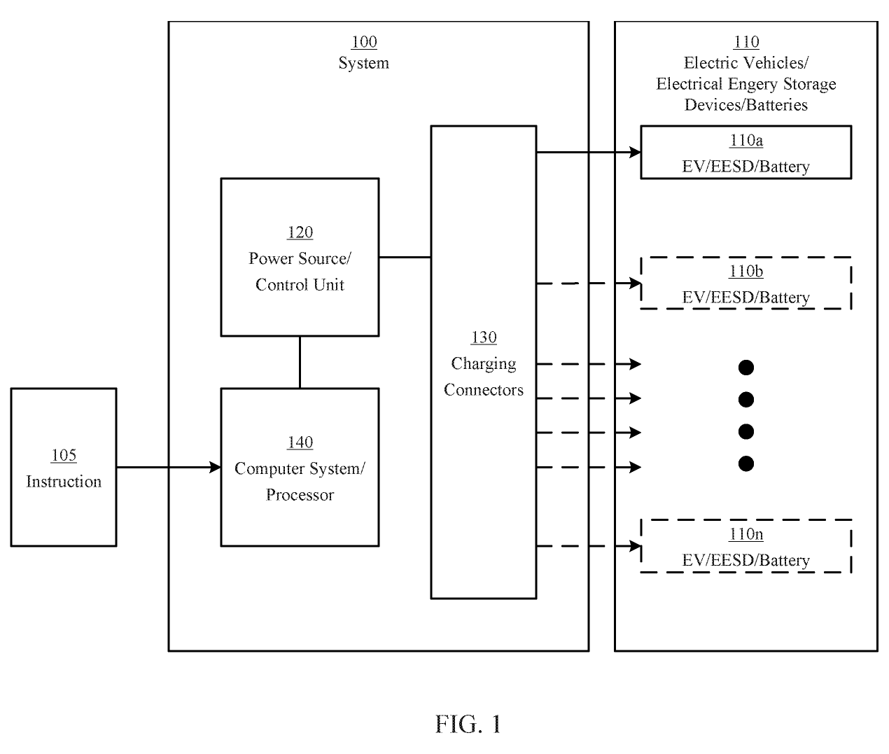

FIG. 1 illustrates an embodiment of a management system 100 for a fleet of electric vehicles and/or a set of electrical energy storage devices/batteries (referred to herein as electric vehicles 110 or electrical energy storage devices 110), in accordance with various embodiments. As illustrated in FIG. 1, the system 100 includes a power source 120 (which may include a control unit) and a plurality of charging connectors 130 coupled to the power source 120. In various embodiments, the plurality of charging connectors 130 can be configured to supply a current from the power source 120 to one or more electric vehicles 110 of the fleet. The system 100 includes a computer system/processor 140 that is configured to execute machine-readable instructions borne by a non-transitory computer-readable memory device. The instructions may cause the processor 140 to receive an instruction 105 from a customer or an external source. The instruction 105 may include a power distribution scheme for charging the one or more electric vehicles 110 of the fleet, such as electric vehicle 110a or electric vehicle 110b, or any suitable electric vehicle 110n. Once the instruction is received, the processor 140 may continue to obtain a dataset associated with the fleet of electric vehicles 110.

In various embodiments, the dataset obtained by the processor 140 may include one or more data features that are associated with the fleet of electric vehicles. The data features may include dynamic data and historical usage data, which are associated with the fleet of electric vehicles. For example, non-limiting data features of the dynamic data may include a state of charge (SOC), a state of health (SOH), an operating voltage, an operating current, or a usage pattern for each of the electrical vehicles in the fleet, in accordance with one or more embodiments. In one or more embodiments, the historical usage data, for example, may include times of use occurrence for, such as, a plurality of times in a day, a plurality of days of a week, a plurality of weeks of a month, or a plurality of months of a year. In one or more embodiments, the historical usage data may include a usage pattern for each electrical vehicle in the fleet that may include, for example but not limited to, a charge and discharge profile for each electrical vehicle in the fleet.

Once the dataset is received, the system 100/the processor 140 may continue to analyze the one or more data features using a machine learning model to generate a predicted action in response to the instruction received and instruct the power source to distribute power to the one or more electric vehicles of the fleet according to the predicted action. In various embodiments, the predicted action generated by the machine learning model may include determining an optimal current for charging a specific electrical energy storage device of the set, determining a charge limit for a specific electrical energy storage device of the set, determining a charge duration for a specific electrical energy storage device of the set, determining that one or more specific electrical energy storage devices of the set receives power from the power source, and/or determining that one or more specific electrical energy storage devices of the set discontinues receiving power from the power source.

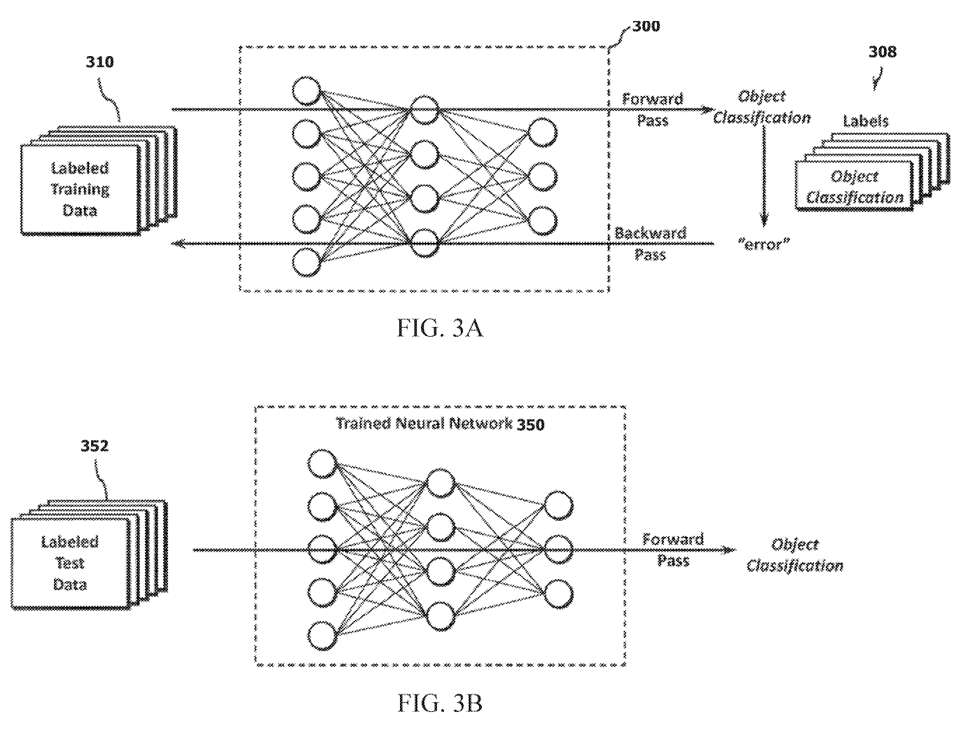

In one or more embodiments, the machine learning model used to generate the predicted action may be trained as described further below with respect to FIG. 3. In one or more embodiments, the machine learning model may be trained using one or more data features from a catalog of electric vehicles, wherein the one or more data features comprise dynamic data comprising states of charge (SOCs) and states of health (SOHs) associated with the catalog of electrical vehicles, historical usage profiles associated with the catalog of electrical vehicles, and/or a utility energy usage profile of a facility proximate the power source. In some embodiments, the machine learning model may be trained using utilization rates and prioritization rates of each electrical vehicle in the fleet.

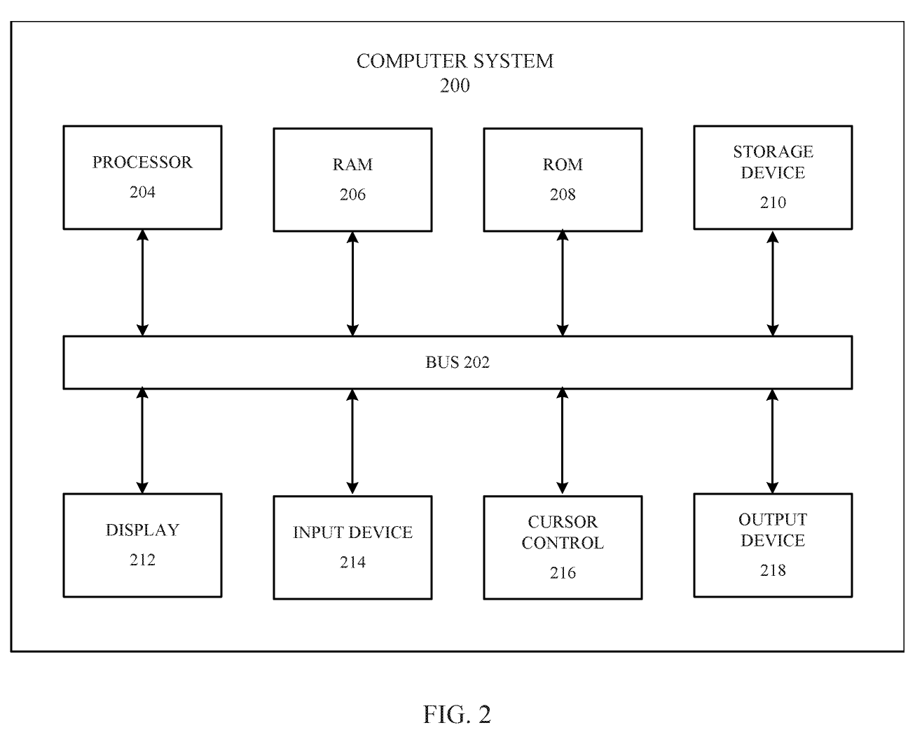

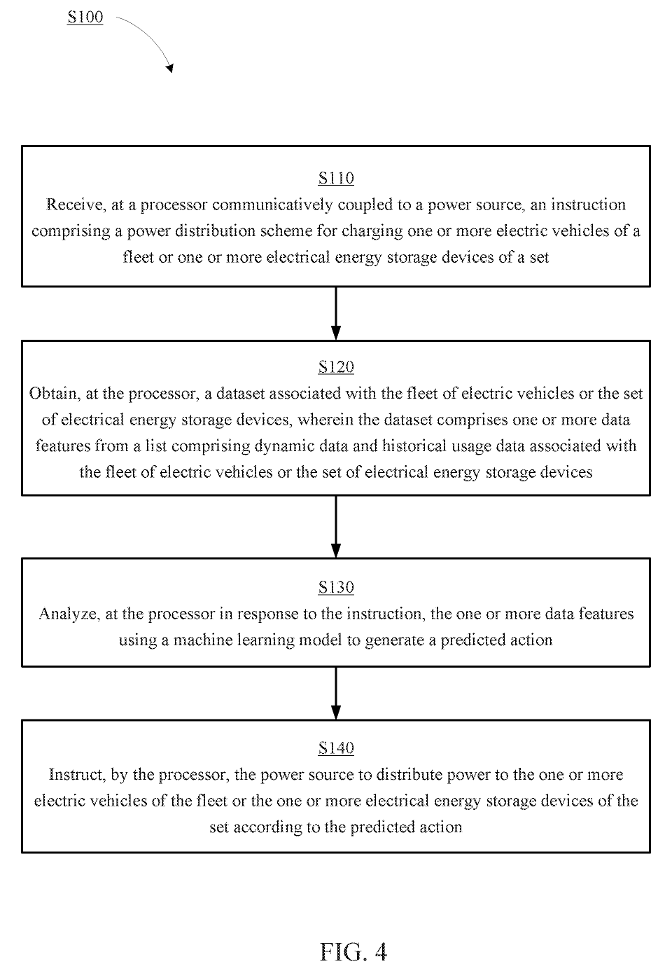

FIG. 2 illustrates a block diagram of a computer system/processor 200 used in the management system 100 of FIG. 1, in accordance with various embodiments. Computer system 200 may be used as a processor 140 for the system 100 as described with respect to FIG. 1 and a method S100, as described further below, with respect to FIG. 4.

In one or more examples, computer system 200 can include a bus 202 or other communication mechanism for communicating information, and a processor 204 coupled with bus 202 for processing information. In various embodiments, computer system 200 can also include a memory, which can be a random-access memory (RAM) 206 or other dynamic storage device, coupled to bus 202 for determining instructions to be executed by processor 204. Memory also can be used for storing temporary variables or other intermediate information during execution of instructions to be executed by processor 204. In various embodiments, computer system 200 can further include a read only memory (ROM) 208 or other static storage device coupled to bus 202 for storing static information and instructions for processor 204. A storage device 210, such as a magnetic disk or optical disk, can be provided and coupled to bus 202 for storing information and instructions.

In various embodiments, computer system 200 can be coupled via bus 202 to a display 212, such as a cathode ray tube (CRT), liquid crystal display (LCD), or light emitting diode (LED) for displaying information to a computer user. An input device 214, including alphanumeric and other keys, can be coupled to bus 202 for communicating information and command selections to processor 204. Another type of user input device is a cursor control 216, such as a mouse, a joystick, a trackball, a gesture input device, a gaze-based input device, or cursor direction keys for communicating direction information and command selections to processor 204 and for controlling cursor movement on display 212. This input device 214 typically has two degrees of freedom in two axes, a first axis (e.g., x) and a second axis (e.g., y), that allows the device to specify positions in a plane. However, it should be understood that input devices 214 allowing for three-dimensional (e.g., x, y, and z) cursor movement are also contemplated herein.

Consistent with certain implementations of the present teachings, results can be provided by computer system 200 in response to processor 204 executing one or more sequences of one or more instructions contained in RAM 206. Such instructions can be read into RAM 206 from another computer-readable medium or computer-readable storage medium, such as storage device 210. Execution of the sequences of instructions contained in RAM 206 can cause processor 204 to perform the processes described herein. Alternatively, hard-wired circuitry can be used in place of or in combination with software instructions to implement the present teachings. Thus, implementations of the present teachings are not limited to any specific combination of hardware circuitry and software.

The term “computer-readable medium” (e.g., data store, data storage, storage device, data storage device, etc.) or “computer-readable storage medium” as used herein refers to any media that participates in providing instructions to processor 204 for execution. Such a medium can take many forms, including but not limited to, non-volatile media, volatile media, and transmission media. Examples of non-volatile media can include, but are not limited to, optical, solid state, magnetic disks, such as storage device 210. Examples of volatile media can include, but are not limited to, dynamic memory, such as RAM 206. Examples of transmission media can include, but are not limited to, coaxial cables, copper wire, and fiber optics, including the wires that comprise bus 202.

Common forms of computer-readable media include, for example, a floppy disk, a flexible disk, hard disk, magnetic tape, or any other magnetic medium, a CD-ROM, any other optical medium, punch cards, paper tape, any other physical medium with patterns of holes, a RAM, PROM, and EPROM, a FLASH-EPROM, any other memory chip or cartridge, or any other tangible medium from which a computer can read.

In addition to computer readable medium, instructions or data can be provided as signals on transmission media included in a communications apparatus or system to provide sequences of one or more instructions to processor 204 of computer system 200 for execution. For example, a communication apparatus may include a transceiver having signals indicative of instructions and data. The instructions and data are configured to cause one or more processors to implement the functions outlined in the disclosure herein. Representative examples of data communications transmission connections can include, but are not limited to, telephone modem connections, wide area networks (WAN), local area networks (LAN), infrared data connections, NFC connections, optical communications connections, etc.

It should be appreciated that the methodologies described herein, flow charts, diagrams, and accompanying disclosure can be implemented using computer system 200 as a standalone device or on a distributed network of shared computer processing resources such as a cloud computing network.

The methodologies described herein may be implemented by various means depending upon the application. For example, these methodologies may be implemented in hardware, firmware, software, or any combination thereof. For a hardware implementation, the processing unit may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

In various embodiments, the methods of the present teachings may be implemented as firmware and/or a software program and applications written in conventional programming languages such as C, C++, Python, etc. If implemented as firmware and/or software, the embodiments described herein can be implemented on a non-transitory computer-readable medium in which a program is stored for causing a computer to perform the methods described above. It should be understood that the various engines described herein can be provided on a computer system, such as computer system 200, whereby processor 204 would execute the analyses and determinations provided by these engines, subject to instructions provided by any one of, or a combination of, the memory components RAM 206, ROM, 208, or storage device 210 and user input provided via input device 214.

FIG. 3A illustrates an example machine learning model or a neural network training process used in in the management system 100 of FIG. 1, in accordance with one or more embodiments. As illustrated in FIG. 3A, an example a machine learning model or a neural network that may be used to generate trained training models are described, in accordance with one or more embodiments. The neural network 300 is implemented as a recurrent neural network, artificial neural network or other suitable neural network that receives a labeled training dataset 310 to produce object detection information 308 for each data sample. The training dataset may include one or more data features from a list comprising dynamic data and historical usage data associated with a fleet of electric vehicles, as described above with respect to the data features associated with the electric vehicles 110 as described with respect to FIG. 1.

The training includes a forward pass through the neural network 300 to produce object detection and classification information, such as an object type, an object classification, and a confidence level in the object classification. Each data sample is labeled with the correct classification and the output of the neural network 300 is compared to the correct label. If the neural network 300 mislabels the input data, then a backward pass through the neural network 300 may be used to adjust the neural network to correct for the misclassification.

FIG. 3B illustrates a validation process for the neural network of FIG. 3A, in accordance with one or more embodiments. As illustrated in FIG. 3B, a trained neural network 350, may then be tested for accuracy using a set of labeled test data 352. The trained neural network 350 may then be implemented in a processor to detect and classify objects.

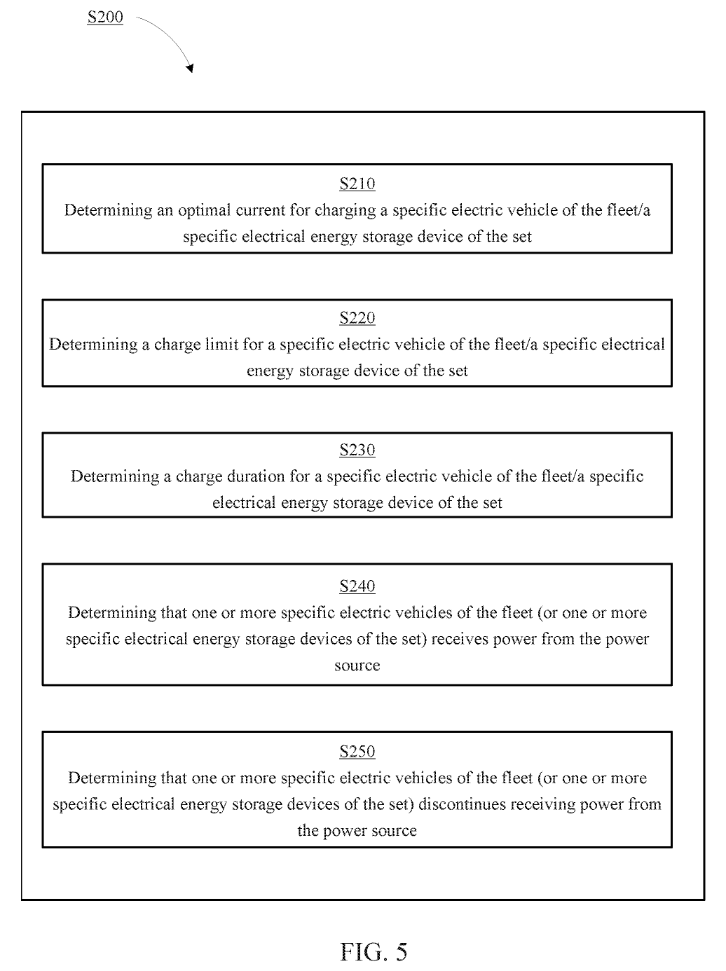

In one or more embodiments, the trained neural network 350 may be used, for example, with the method S100 as described respectively with FIG. 4. In some embodiments, the trained neural network 350 can be implemented in the analysis step of the method S100 to generate a predicted action, which can be one or more of the actions described with respect to FIG. 5.

FIG. 4 illustrates a method S100 for managing a fleet of electric vehicles and/or a set of electrical energy storage devices/batteries, in accordance with various embodiments. In one or more embodiments, the method S100 is a computer-based method that can be executed on a processor of a computer, such as the computer system/processor 200 described with respect to FIG. 2. As illustrated in FIG. 4, the method S100 for managing a fleet of electric vehicles and/or a set of electrical energy storage devices/batteries may include at step S110, receiving, at a processor communicatively coupled to a power source, an instruction comprising a power distribution scheme for charging one or more electric vehicles of the fleet. The processor in the method S100 may be the computer system/processor 100 and/or 200 as described with respect to FIGS. 1 and 2, and the power source may be the power source 120 with the control unit as described with respect to the system 100 of FIG. 1. In accordance with one or more embodiments, the power distribution scheme may include a specific instruction to curtail power distribution by the power source, for example, to limit or restrict the power source’s availability to supply to the electric vehicles when the power source needs to be reserved some of its power for other purposes. In some embodiments, the power distribution scheme may include a particular instruction to limit a maximum energy capacity or power available to the power source for distribution. In one or more embodiments, the power distribution scheme may include an instruction to set a duration or a period of time for curtailment of power distribution by the power source, for a specific electric vehicle, a specific electrical energy storage device/battery, for any number of reasons.

The method S100 may include at step S120, obtaining, at the processor, a dataset associated with the fleet of electric vehicles, as illustrated in FIG. 4. In various embodiments, the dataset may include one or more data features from a list of features comprising dynamic data and historical usage data associated with the fleet of electric vehicles. In one or more embodiments, the dynamic data may include for example, but not limited to, a state of charge (SOC), a state of health (SOH), an operating voltage, an operating current, or a usage pattern for each electrical vehicle in the fleet or each electrical energy storage device in the set. In one or more embodiments, the historical usage data may include for example, but not limited to, times of use for a plurality of times in a day, a plurality of days of a week, a plurality of weeks of a month, or a plurality of months of a year. In one or more embodiments, the historical usage data may include for example, but not limited to, a usage pattern for each electrical vehicle in the fleet comprising a charge and discharge profile for each electrical vehicle in the fleet.

As further illustrated in FIG. 4, the method S100 may include at step S130, analyzing, at the processor in response to the instruction, the one or more data features using a machine learning model to generate a predicted action; and at step S140, instructing, by the processor, the power source to distribute power to the one or more electric vehicles of the fleet according to the predicted action. In one or more embodiments, the predicted action may include one of: determining an optimal current for charging a specific electric vehicle of the fleet; determining a charge limit for a specific electric vehicle of the fleet; determining a charge duration for a specific electric vehicle of the fleet; determining that one or more specific electric vehicles of the fleet receives power from the power source; or determining that one or more specific electric vehicles of the fleet discontinues receiving power from the power source.

In one or more embodiments of the method S100, the machine learning model may be trained as described above with respect to FIG. 3. In one or more embodiments, the machine learning model used in the method S100 may be trained using one or more data features from a catalog of electric vehicles, wherein the one or more data features comprise dynamic data comprising states of charge (SOCs) and states of health (SOHs) associated with the catalog of electrical vehicles, historical usage profiles associated with the catalog of electrical vehicles, and/or a utility energy usage profile of a facility proximate the power source. In one or more embodiments, the machine learning model may be trained using utilization rates and prioritization rates of each electrical vehicle in the fleet.

In various embodiments, the method S100 may optional include obtaining an updated dataset comprising updated values of the one or more data features, analyzing the updated values of the one or more data features to generate an updated predicted action, and further instructing the power source to distribute power to the one or more electric vehicles of the fleet according to the updated predicted action. In one or more embodiments, the updated dataset may be obtained after receiving an updated instruction by the processor. In one or more embodiments, the updated dataset may be obtained after a preset duration, a time of day, or after the SOC (or any other suitable parameters) have changed for a certain percentage. In one or more embodiments, each electrical vehicle in the fleet may include an electrical energy storage device in a form of a lithium-ion battery, a solid-state lithium-ion battery, or a lead acid battery.

FIG. 5 illustrates an example set 500 of predicted actions generated by the machine learning model used in the management system 100 of FIG. 1, in accordance with various embodiments. As illustrated in FIG. 5, the set 500 of predicted actions may include action S210 - determining an optimal current for charging a specific electric vehicle of the fleet; action S220 - determining a charge limit for a specific electric vehicle of the fleet; action S230 - determining a charge duration for a specific electric vehicle of the fleet; action S240 - determining that one or more specific electric vehicles of the fleet receives power from the power source; or action S250 - determining that one or more specific electric vehicles of the fleet discontinues receiving power from the power source.

### RECITATION OF EMBODIMENTS

Embodiment 1. A system for managing a fleet of electric vehicles, comprising: a power source; a plurality of charging connectors coupled to the power source, the plurality of charging connectors configured to supply a current from the power source to one or more electric vehicles of the fleet; and a processor configured to execute machine-readable instructions borne by a non-transitory computer-readable memory device to cause the processor to: receive an instruction comprising a power distribution scheme for charging the one or more electric vehicles of the fleet; obtain a dataset associated with the fleet of electric vehicles, wherein the dataset comprises one or more data features from a list comprising dynamic data and historical usage data associated with the fleet of electric vehicles; analyze, in response to the instruction, the one or more data features using a machine learning model to generate a predicted action; and instruct the power source to distribute power to the one or more electric vehicles of the fleet according to the predicted action.

Embodiment 2. The system of Embodiment 1, wherein the predicted action comprises one of: determining an optimal current for charging a specific electric vehicle of the fleet; determining a charge limit for a specific electric vehicle of the fleet; determining a charge duration for a specific electric vehicle of the fleet; determining that one or more specific electric vehicles of the fleet receives power from the power source; or determining that one or more specific electric vehicles of the fleet discontinues receiving power from the power source.

Embodiment 3. The system of Embodiments 1 or 2, wherein the power distribution scheme includes an instruction to curtail power distribution by the power source (e.g., restriction of the power source’s availability to supply to the EVs).

Embodiment 4. The system of any one of Embodiments 1-3, wherein the power distribution scheme includes an instruction to limit a maximum energy capacity or power available to the power source for distribution.

Embodiment 5. The system of any one of Embodiments 1-4, wherein the power distribution scheme includes an instruction to set a duration or a period of time for curtailment of power distribution by the power source.

Embodiment 6. The system of any one of Embodiments 1-5, wherein the dynamic data comprise a state of charge (SOC), a state of health (SOH), an operating voltage, an operating current, or a usage pattern for each electrical vehicle in the fleet.

Embodiment 7. The system of any one of Embodiments 1-6, wherein the historical usage data comprise times of use for a plurality of times in a day, a plurality of days of a week, a plurality of weeks of a month, or a plurality of months of a year.

Embodiment 8. The system of any one of Embodiments 1-7, wherein the historical usage data comprise a usage pattern for each electrical vehicle in the fleet comprising a charge and discharge profile for each electrical vehicle in the fleet.

Embodiment 9. The system of any one of Embodiments 1-8, wherein the machine learning model is trained using one or more data features from a catalog of electric vehicles, wherein the one or more data features comprise dynamic data comprising states of charge (SOCs) and states of health (SOHs) associated with the catalog of electrical vehicles, historical usage profiles associated with the catalog of electrical vehicles, and/or a utility energy usage profile of a facility proximate the power source.

Embodiment 10. The system of any one of Embodiments 1-9, wherein the machine learning model is trained using utilization rates and prioritization rates of each electrical vehicle in the fleet.

Embodiment 11. The system of any one of Embodiments 1-10, wherein the machine-readable instructions further cause the processor to: obtain an updated dataset comprising updated values of the one or more data features; analyze the updated values of the one or more data features to generate an updated predicted action; and further instruct the power source to distribute power to the one or more electric vehicles of the fleet according to the updated predicted action.

Embodiment 12. The system of Embodiment 11, wherein the updated dataset is obtained after receiving an updated instruction by the processor.

Embodiment 13. The system of Embodiment 11, wherein the updated dataset is obtained after a preset duration, a time of day, or after the SOC (or any other suitable parameters) have changed for a certain percentage.

Embodiment 14. The system of any one of Embodiments 1-13, wherein each electrical vehicle in the fleet comprises an electrical energy storage device in a form of a lithium-ion battery, a solid-state lithium-ion battery, or a lead acid battery.

Embodiment 15. A method for managing a fleet of electric vehicles, comprising: receiving, at a processor communicatively coupled to a power source, an instruction comprising a power distribution scheme for charging one or more electric vehicles of the fleet; obtaining, at the processor, a dataset associated with the fleet of electric vehicles, wherein the dataset comprises one or more data features from a list comprising dynamic data and historical usage data associated with the fleet of electric vehicles; analyzing, at the processor in response to the instruction, the one or more data features using a machine learning model to generate a predicted action; and instructing, by the processor, the power source to distribute power to the one or more electric vehicles of the fleet according to the predicted action.

Embodiment 16. The method of Embodiment 15, wherein the predicted action comprises one of: determining an optimal current for charging a specific electric vehicle of the fleet; determining a charge limit for a specific electric vehicle of the fleet; determining a charge duration for a specific electric vehicle of the fleet; determining that one or more specific electric vehicles of the fleet receives power from the power source; or determining that one or more specific electric vehicles of the fleet discontinues receiving power from the power source.

Embodiment 17. The method of Embodiments 15 or 16, wherein the power distribution scheme includes an instruction to curtail power distribution by the power source (e.g., restriction of the power source’s availability to supply to the EVs).

Embodiment 18. The method of any one of Embodiments 15-17, wherein the power distribution scheme includes an instruction to limit a maximum energy capacity or power available to the power source for distribution.

Embodiment 19. The method of any one of Embodiments 15-18, wherein the power distribution scheme includes an instruction to set a duration or a period of time for curtailment of power distribution by the power source.

Embodiment 20. The method of any one of Embodiments 15-19, wherein the dynamic data comprise a state of charge (SOC), a state of health (SOH), an operating voltage, an operating current, or a usage pattern for each electrical vehicle in the fleet.

Embodiment 21. The method of any one of Embodiments 15-20, wherein the historical usage data comprise times of use for a plurality of times in a day, a plurality of days of a week, a plurality of weeks of a month, or a plurality of months of a year.

Embodiment 22. The method of any one of Embodiments 15-21, wherein the historical usage data comprise a usage pattern for each electrical vehicle in the fleet comprising a charge and discharge profile for each electrical vehicle in the fleet.

Embodiment 23. The method of any one of Embodiments 15-22, wherein the machine learning model is trained using one or more data features from a catalog of electric vehicles, wherein the one or more data features comprise dynamic data comprising states of charge (SOCs) and states of health (SOHs) associated with the catalog of electrical vehicles, historical usage profiles associated with the catalog of electrical vehicles, and/or a utility energy usage profile of a facility proximate the power source.

Embodiment 24. The method of any one of Embodiments 15-23, wherein the machine learning model is trained using utilization rates and prioritization rates of each electrical vehicle in the fleet.

Embodiment 25. The method of any one of Embodiments 15-24, further comprising: obtaining an updated dataset comprising updated values of the one or more data features; analyzing the updated values of the one or more data features to generate an updated predicted action; and further instructing the power source to distribute power to the one or more electric vehicles of the fleet according to the updated predicted action.

Embodiment 26. The method of Embodiment 25, wherein the updated dataset is obtained after receiving an updated instruction by the processor.

Embodiment 27. The method of Embodiment 25, wherein the updated dataset is obtained after a preset duration, a time of day, or after the SOC (or any other suitable parameters) have changed for a certain percentage.

Embodiment 28. The method of any one of Embodiments 15-27, wherein each electrical vehicle in the fleet comprises an electrical energy storage device in a form of a lithium-ion battery, a solid-state lithium-ion battery, or a lead acid battery.

Embodiment 29. A system for managing a set of electrical energy storage devices, comprising: a power source; a plurality of charging connectors coupled to the power source, the plurality of charging connectors configured to supply a current from the power source to one or more electrical energy storage devices of the set; and a processor configured to execute machine-readable instructions borne by a non-transitory computer-readable memory device to cause the processor to: receive an instruction comprising a power distribution scheme for charging the one or more electrical energy storage devices of the set; obtain a dataset associated with the set of electrical energy storage devices, wherein the dataset comprises one or more data features from a list comprising dynamic data and historical usage data associated with the set of electrical energy storage devices; analyze, in response to the instruction, the one or more data features using a machine learning model to generate a predicted action; and instruct the power source to distribute power to the one or more electrical energy storage devices of the set according to the predicted action.

Embodiment 30. The system of Embodiment 29, wherein the predicted action comprises one of: determining an optimal current for charging a specific electrical energy storage device of the set; determining a charge limit for a specific electrical energy storage device of the set; determining a charge duration for a specific electrical energy storage device of the set; determining that one or more specific electrical energy storage devices of the set receives power from the power source; or determining that one or more specific electrical energy storage devices of the set discontinues receiving power from the power source.

Embodiment 31. The system of Embodiments 29 or 30, wherein the power distribution scheme includes an instruction to curtail power distribution by the power source (e.g., restriction of the power source’s availability to supply to the set of electrical energy storage devices).

Embodiment 32. The system of any one of Embodiments 29-31, wherein the power distribution scheme includes an instruction to limit a maximum energy capacity or power available to the power source for distribution.

Embodiment 33. The system of any one of Embodiments 29-32, wherein the power distribution scheme includes an instruction to set a duration or a period of time for curtailment of power distribution by the power source.

Embodiment 34. The system of any one of Embodiments 29-33, wherein the dynamic data comprise a state of charge (SOC), a state of health (SOH), an operating voltage, an operating current, or a usage pattern for each electrical energy storage device in the set.

Embodiment 35. The system of any one of Embodiments 29-34, wherein the historical usage data comprise times of use for a plurality of times in a day, a plurality of days of a week, a plurality of weeks of a month, or a plurality of months of a year.

Embodiment 36. The system of any one of Embodiments 29-35, wherein the historical usage data comprise a usage pattern for each electrical energy storage device in the set comprising a charge and discharge profile for each electrical energy storage device in the set.

Embodiment 37. The system of any one of Embodiments 29-36, wherein the machine learning model is trained using one or more data features from a catalog of electrical energy storage devices, wherein the one or more data features comprise dynamic data comprising states of charge (SOCs) and states of health (SOHs) associated with the catalog of electrical energy storage devices, historical usage profiles associated with the catalog of electrical energy storage devices, and/or a utility energy usage profile of a facility proximate the power source.

Embodiment 38. The system of any one of Embodiments 29-37, wherein the machine learning model is trained using utilization rates and prioritization rates of each electrical energy storage device in the set.

Embodiment 39. The system of any one of Embodiments 29-38, wherein the machine-readable instructions further cause the processor to: obtain an updated dataset comprising updated values of the one or more data features; analyze the updated values of the one or more data features to generate an updated predicted action; and further instruct the power source to distribute power to the one or more electrical energy storage devices of the set according to the updated predicted action.

Embodiment 40. The system of Embodiment 39, wherein the updated dataset is obtained after receiving an updated instruction by the processor.

Embodiment 41. The system of Embodiment 39, wherein the updated dataset is obtained after a preset duration, a time of day, or after the SOC (or any other suitable parameters) have changed for a certain percentage.

Embodiment 42. The system of any one of Embodiments 29-41, wherein each electrical energy storage device in the set comprises a lithium-ion battery, a solid-state lithium-ion battery, or a lead acid battery.

1. A system for managing a fleet of electric vehicles, comprising:
a power source;
a plurality of charging connectors coupled to the power source, the plurality of charging connectors configured to supply a current from the power source to one or more electric vehicles of the fleet; and
a processor configured to execute machine-readable instructions borne by a non-transitory computer-readable memory device to cause the processor to:
receive an instruction comprising a power distribution scheme for charging the one or more electric vehicles of the fleet;
obtain a dataset associated with the fleet of electric vehicles, wherein the dataset comprises one or more data features from a list comprising dynamic data and historical usage data associated with the fleet of electric vehicles;
analyze, in response to the instruction, the one or more data features using a machine learning model to generate a predicted action; and
instruct the power source to distribute power to the one or more electric vehicles of the fleet according to the predicted action.

2. The system of claim 1, wherein the predicted action comprises one of:
determining an optimal current for charging a specific electric vehicle of the fleet;
determining a charge limit for a specific electric vehicle of the fleet;
determining a charge duration for a specific electric vehicle of the fleet;
determining that one or more specific electric vehicles of the fleet receives power from the power source; or
determining that one or more specific electric vehicles of the fleet discontinues receiving power from the power source.

3. The system of claim 1, wherein the power distribution scheme includes an instruction to curtail power distribution by the power source (e.g., restriction of the power source’s availability to supply to the EVs).

4. The system of claim 1, wherein the power distribution scheme includes an instruction to limit a maximum energy capacity or power available to the power source for distribution.

5. The system of claim 1, wherein the power distribution scheme includes an instruction to set a duration or a period of time for curtailment of power distribution by the power source.

6. The system of claim 1, wherein the dynamic data comprise a state of charge (SOC), a state of health (SOH), an operating voltage, an operating current, or a usage pattern for each electrical vehicle in the fleet.

7. The system of claim 1, wherein the historical usage data comprise a usage pattern for each electrical vehicle in the fleet comprising a charge and discharge profile for each electrical vehicle in the fleet.

8. The system of claim 1, wherein the machine learning model is trained using one or more data features from a catalog of electric vehicles, wherein the one or more data features comprise dynamic data comprising states of charge (SOCs) and states of health (SOHs) associated with the catalog of electrical vehicles, historical usage profiles associated with the catalog of electrical vehicles, and/or a utility energy usage profile of a facility proximate the power source.

9. The system of claim 1, wherein the machine-readable instructions further cause the processor to:
obtain an updated dataset comprising updated values of the one or more data features;
analyze the updated values of the one or more data features to generate an updated predicted action; and
further instruct the power source to distribute power to the one or more electric vehicles of the fleet according to the updated predicted action.

10. The system of claim 1, wherein each electrical vehicle in the fleet comprises an electrical energy storage device in a form of a lithium-ion battery, a solid-state lithium-ion battery, or a lead acid battery.

11. A method for managing a fleet of electric vehicles, comprising:
receiving, at a processor communicatively coupled to a power source, an instruction comprising a power distribution scheme for charging one or more electric vehicles of the fleet;
obtaining, at the processor, a dataset associated with the fleet of electric vehicles, wherein the dataset comprises one or more data features from a list comprising dynamic data and historical usage data associated with the fleet of electric vehicles;
analyzing, at the processor in response to the instruction, the one or more data features using a machine learning model to generate a predicted action; and
instructing, by the processor, the power source to distribute power to the one or more electric vehicles of the fleet according to the predicted action.

12. The method of claim 11, wherein the predicted action comprises one of:
determining an optimal current for charging a specific electric vehicle of the fleet;
determining a charge limit for a specific electric vehicle of the fleet;
determining a charge duration for a specific electric vehicle of the fleet;
determining that one or more specific electric vehicles of the fleet receives power from the power source; or
determining that one or more specific electric vehicles of the fleet discontinues receiving power from the power source.

13. The method of claim 11, wherein the historical usage data comprise times of use for a plurality of times in a day, a plurality of days of a week, a plurality of weeks of a month, or a plurality of months of a year.

14. The method of claim 11, wherein the machine learning model is trained using one or more data features from a catalog of electric vehicles, wherein the one or more data features comprise dynamic data comprising states of charge (SOCs) and states of health (SOHs) associated with the catalog of electrical vehicles, historical usage profiles associated with the catalog of electrical vehicles, and/or a utility energy usage profile of a facility proximate the power source.

15. The method of claim 11, further comprising:
obtaining an updated dataset comprising updated values of the one or more data features;
analyzing the updated values of the one or more data features to generate an updated predicted action; and
further instructing the power source to distribute power to the one or more electric vehicles of the fleet according to the updated predicted action.

16. A system for managing a set of electrical energy storage devices, comprising:
a power source;
a plurality of charging connectors coupled to the power source, the plurality of charging connectors configured to supply a current from the power source to one or more electrical energy storage devices of the set; and
a processor configured to execute machine-readable instructions borne by a non-transitory computer-readable memory device to cause the processor to:
receive an instruction comprising a power distribution scheme for charging the one or more electrical energy storage devices of the set;
obtain a dataset associated with the set of electrical energy storage devices, wherein the dataset comprises one or more data features from a list comprising dynamic data and historical usage data associated with the set of electrical energy storage devices;
analyze, in response to the instruction, the one or more data features using a machine learning model to generate a predicted action; and
instruct the power source to distribute power to the one or more electrical energy storage devices of the set according to the predicted action.

17. The system of claim 16, wherein the predicted action comprises one of:
determining an optimal current for charging a specific electrical energy storage device of the set;
determining a charge limit for a specific electrical energy storage device of the set;
determining a charge duration for a specific electrical energy storage device of the set;
determining that one or more specific electrical energy storage devices of the set receives power from the power source; or
determining that one or more specific electrical energy storage devices of the set discontinues receiving power from the power source.

18. The system of claim 16, wherein the historical usage data comprise times of use for a plurality of times in a day, a plurality of days of a week, a plurality of weeks of a month, or a plurality of months of a year.

19. The system of claim 16, wherein the machine learning model is trained using one or more data features from a catalog of electrical energy storage devices, wherein the one or more data features comprise dynamic data comprising states of charge (SOCs) and states of health (SOHs) associated with the catalog of electrical energy storage devices, historical usage profiles associated with the catalog of electrical energy storage devices, and/or a utility energy usage profile of a facility proximate the power source.

20. The system of claim 16, wherein the machine-readable instructions further cause the processor to:
obtain an updated dataset comprising updated values of the one or more data features;
analyze the updated values of the one or more data features to generate an updated predicted action; and
further instruct the power source to distribute power to the one or more electrical energy storage devices of the set according to the updated predicted action.
